(19) United States
(12) Patent Application Publication
(10) Pub. No.: US 2016/0056300 A1
(43) Pub. Date: Feb. 25, 2016

(54) THIN FILM TRANSISTOR AND FABRICATING METHOD THEREOF

(71) Applicant: Chunghwa Picture Tubes, LTD., Taoyuan County (TW)

(72) Inventors: Wei-Lung Li, Taoyuan County (TW); Yu-Fan Hu, Kaohsiung City (TW); Ting-Chu Yeh, Kaohsiung City (TW); Miao-Chi Shih, New Taipei City (TW)

(21) Appl. No.: 14/520,359

(22) Filed: Oct. 22, 2014

(30) Foreign Application Priority Data
Aug. 19, 2014 (TW) 103128432

(51) Int. Cl. H01L 29/786; H01L 21/441; H01L 21/31; H01L 21/46; H01L 23/528; H01L 21/283; H01L 29/66; H01L 21/768

(52) U.S. Cl. CPC H01L 29/78696; H01L 29/66969; H01L 21/441; H01L 21/76838; H01L 21/46; H01L 29/66765; H01L 29/66772; H01L 29/7869; H01L 29/78654; H01L 29/78678; H01L 29/78669; H01L 23/528; H01L 21/283; H01L 21/31

(57) ABSTRACT

A thin film transistor and a fabricating method thereof is provided. The thin film transistor includes a gate, a gate insulation layer, a semiconductor layer, a conductive pattern, a first electrode and a second electrode. The gate is disposed on a substrate. The gate insulation layer is disposed on the substrate to cover the gate.

The semiconductor layer is disposed on the gate insulation layer. The conductive pattern, the first electrode and the second electrode are disposed on semiconductor layer. A first distance is formed between the first electrode and the second electrode, wherein the first electrode and the second electrode are a source and a drain. The conductive pattern is electrically connected to the first electrode, and a second distance smaller than the first distance is formed between the conductive pattern and the second electrode to define a channel.

### CROSS-REFERENCE TO RELATED APPLICATION

This application claims the priority benefit of Taiwan application serial no. 103128432, filed on Aug. 19, 2014. The entirety of the above-mentioned patent application is hereby incorporated by reference herein and made a part of this specification.

### BACKGROUND OF THE INVENTION

1. Field of the Invention

The invention relates to an electronic device and a fabricating method thereof, and particularly relates to a thin film transistor and a fabricating method thereof.

2. Description of Related Art

Patterning of a conductor structure generally proceeds by performing a photolithography process and an etching process. In the photolithography and etching processes, a photoresist material is firstly used to cover a conductor layer, and then an exposure process is performed to the photoresist material with a mask having a specific pattern. Then, a development process is performed to remove a part of the photoresist material, and patterning of the photoresist layer is thus completed. Afterwards, using the patterned photoresist layer as a mask, the etching process is performed to the conductor layer to produce a conductor structure having a specific pattern. In the photolithography and etching processes, a line width and a pitch of the conductor are usually determined by an exposure resolution of an exposing machine.

Taking a thin film transistor in a pixel structure as an example, a pattern of a source and a drain may be defined by the photolithography and etching processes. In addition, a distance between the source and the drain determines a length of a channel of the thin film transistor. However, due to limitation on the exposure resolution of the exposing machine, a window for reducing the length of the channel of the thin film transistor is limited, and it is not able to design a channel having a smaller length. Alternatively, a special mask such as a phase shift mask (PSM) is required to reach a smaller length of the channel. However, such endeavor will result in increasing the fabricating cost of the thin film transistor.

### SUMMARY OF THE INVENTION

The invention provides a method of fabricating a thin film transistor to reduce a length of a channel.

The invention also provides a thin film transistor having a smaller length of a channel.

A method of fabricating a thin film transistor of the invention includes following steps. A gate is formed on a substrate. A gate insulation layer is formed on the substrate to cover the gate. A semiconductor layer is formed on the gate insulation layer. A conductive pattern is formed on the semiconductor layer. A first electrode and a second electrode are formed on the semiconductor layer, wherein a first distance is formed between the first electrode and the second electrode, the first electrode is one of a source and a drain, and the second electrode is the other of the source and the drain. The conductive pattern is electrically connected with the first electrode, and a second distance is formed between the conductive pattern and the second electrode to define a channel, wherein the second distance is smaller than the first distance.

A thin film transistor of the invention includes a gate, a gate insulation layer, a semiconductor layer, a conductive pattern, and a first electrode and a second electrode.

The gate is disposed on a substrate. The gate insulation layer is disposed on the substrate to cover the gate. The semiconductor layer is disposed on the gate insulation layer. The conductive pattern is disposed on the semiconductor layer. The first electrode and the second electrode are disposed on the semiconductor layer, wherein a first distance is formed between the first electrode and the second electrode, the first electrode is one of a source and a drain, and the second electrode is the other of the source and the drain. The conductive pattern is electrically connected with the first electrode, and a second distance is formed between the conductive pattern and the second electrode to define a channel, wherein the second distance is smaller than the first distance.

According to an embodiment of the invention, the conductive pattern is disposed between the first electrode and the semiconductor layer.

According to an embodiment of the invention, the first electrode is disposed between the conductive pattern and the semiconductor layer.

According to an embodiment of the invention, an insulation layer is further included, wherein the insulation layer covers the first electrode and the second electrode, the conductive pattern, and the semiconductor layer exposed between the first electrode and the second electrode.

According to an embodiment of the invention, the first distance is from 3 um to 4 um, and the second distance is from 1 um to 3 um.

Based on the above, by forming the conductive pattern above or under one of the source and the drain, the channel is formed between the conductive pattern and the other of the source and the drain in the invention. In this way, the length of the channel is reduced by controlling the position where the conductive pattern is formed, so as to overcome the issue that the length of the channel is limited by an exposure resolution of an exposing machine. Also, it is not necessary to use a special mask. Besides, since the thin film transistor has a higher driving current, the size of the thin film transistor may be reduced to meet the requirement of the targeted high resolution panel with a slim bezel.

### BRIEF DESCRIPTION OF THE DRAWINGS

FIGS. 1A to 1D are schematic top views illustrating a method of fabricating a thin film transistor according to an embodiment of the invention.

FIGS. 2A to 2D are cross-sectional views along a line I-I′ in FIGS. 1A to 1D.

FIG. 3A is a top schematic view illustrating a thin film transistor according to an embodiment of the invention, and FIG. 3B is a cross-sectional view along a line I-I′ in FIG. 3A.

### DESCRIPTION OF THE EMBODIMENTS

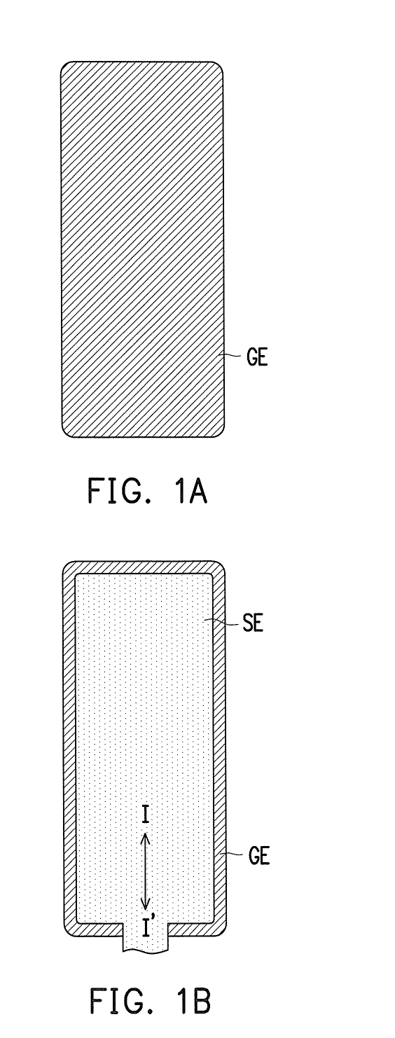

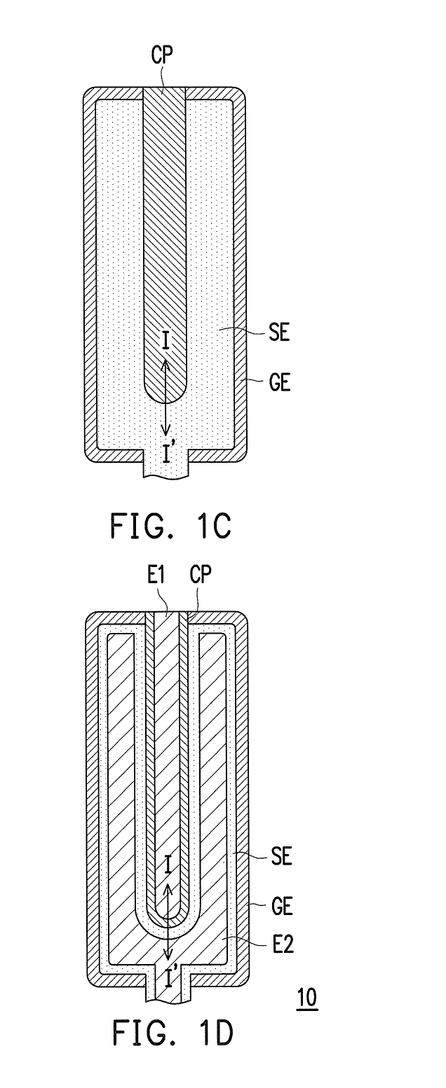

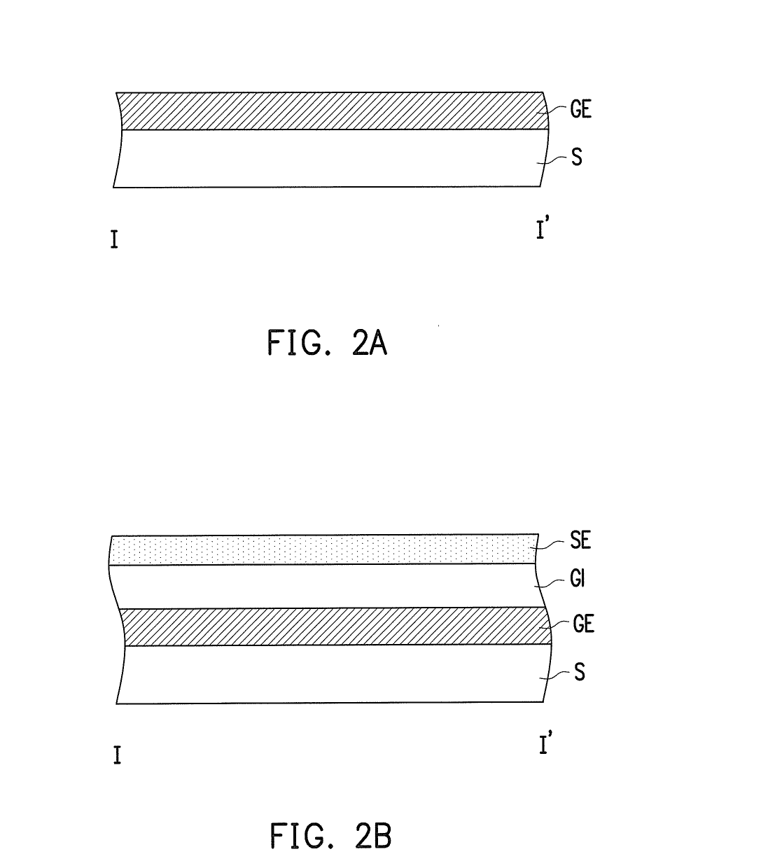

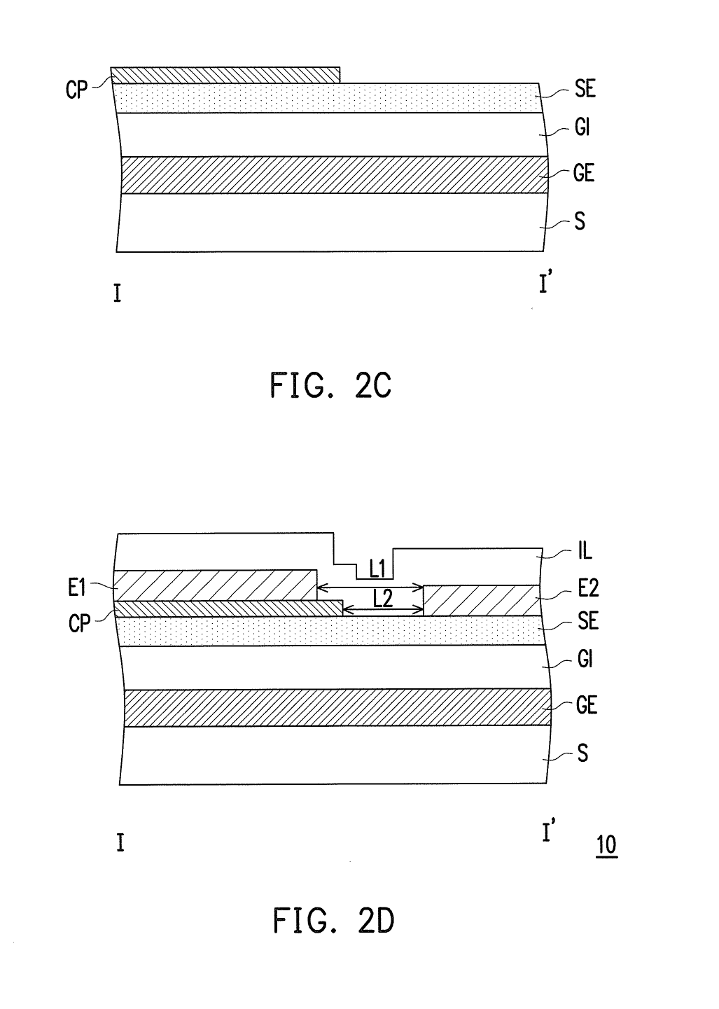

FIGS. 1A to 1D are schematic top views illustrating a method of fabricating a thin film transistor according to an embodiment of the invention, and FIGS. 2A to 2D are cross-sectional views along a line I-I′ in FIGS. 1A to 1D. In addition, a gate insulation layer GI and an insulation layer IL are omitted in FIGS. 1A to 1D. First of all, referring to FIGS. 1A and 2A together, a substrate S is provided. In terms of optical characteristics, the substrate S may be a transparent substrate or an opaque/reflective substrate. A material of the transparent substrate may be selected from glass, quartz, an organic polymer, other suitable materials, or a combination thereof. A material of the opaque/reflective substrate may be selected from a conductive material, metal, wafer, ceramic, other suitable materials, or a combination thereof. It should be noted that if the substrate S is formed of a conductive material, an insulation layer (not shown) needs to be formed on the substrate S before elements of the thin film transistor are formed on the substrate S, so as to prevent a short circuit between the substrate S and the elements of the thin film transistor. In terms of mechanical characteristics, the substrate S may be a rigid substrate or a flexible substrate. A material of the rigid substrate may be selected from glass, quartz, a conductive material, metal, wafer, ceramic, other suitable materials, or a combination thereof A material of the flexible substrate may be selected from ultra-thin glass, an organic polymer (e.g. plastics), other suitable materials, or a combination thereof.

Then, a gate GE is formed on the substrate S. For example, in this embodiment, a conductive layer may be formed on the substrate S. Then, a photolithography process and an etching process are performed to the conductive layer to form the gate GE. The gate GE is usually formed of a metallic material. However, the invention is not limited thereto. In other embodiments, the gate GE may be formed of other conductive materials (e.g. an alloy, nitride of a metallic material, oxide of a metallic material, oxynitride of a metallic material, etc.) or a stack layer of a metallic material and other conductive materials.

Referring to FIGS. 1B and 2B together, then, the gate insulation layer GI is fowled on the substrate S. A material of the gate insulation layer GI may be selected from an inorganic material, an organic material, other suitable materials, or a combination thereof. The inorganic material is, for example, silicon oxide, silicon nitride, silicon oxynitride, other suitable materials, or a stack layer of at least two of the materials. In this embodiment, the gate insulation layer GI may fully cover the gate GE and the substrate S. However, the invention is not limited thereto. In other embodiments, the gate insulation layer GI may also be implemented in other suitable configurations.

Afterwards, a semiconductor layer SE is formed on the gate insulation layer GI. The semiconductor layer SE may be a single-layer or multi-layer structure, and a material of the semiconductor layer SE may be selected from amorphous silicon, polysilicon, micro crystalline silicon, mono crystalline silicon, a metal oxide semiconductor material (e.g. indium-gallium-zinc oxide (IGZO), zinc oxide (ZnO), tin oxide (SnO), indium-zinc oxide (IZO), gallium-zinc oxide (GZO), zinc-tin oxide (ZTO), indium-tin oxide (ITO), etc.), other suitable materials, or a combination thereof.

Referring to FIGS. 1C and 2C together, then, a conductive pattern CP is formed on the semiconductor layer SE. In this embodiment, a conductive layer may be firstly formed on the semiconductor layer SE. Then, a photolithography process and an etching process are performed to the conductive layer to form the conductive pattern CP. In this embodiment, a material of the conductive pattern CP is, for example, a transparent conductive material, such as indium-gallium-zinc oxide (IGZO), zinc oxide (ZnO), tin oxide (SnO), indium-zinc oxide (IZO), gallium-zinc oxide (GZO), zinc-tin oxide (ZTO), indium-tin oxide (ITO), etc. However, the invention is not limited thereto. In other embodiments, the conductive pattern CP may also be formed of a metallic material or other conductive materials (e.g. an alloy, nitride of a metallic material, oxynitride of a metallic material, etc.), or a stack layer of a metallic material and other conductive materials. In addition, the metallic material is, for example, molybdenum (Mo), tungsten (W), aluminum (Al), titanium (Ti), etc.

Referring to FIGS. 1D and 2D, then, a first electrode E1 and a second electrode E2 are formed on the semiconductor layer SE. In addition, a first distance L1 is formed between the first electrode E1 and the second electrode E2. The first electrode E1 is one of a source and a drain, and the second electrode E2 is the other of the source and the drain. In this embodiment, the first electrode E1 is the drain, and the second electrode E2 is a source, for example. However, in another embodiment, the first electrode E1 may be the source, and the second electrode E2 may be the drain. The conductive pattern CP is electrically connected with the first electrode E1. A second distance L2 is formed between the conductive pattern CP and the second electrode E2 to define a channel CH. In addition, the second distance L2 is smaller than the first distance L1. In other words, a length of the channel CH is defined by the conductive pattern CP and the second electrode E2, and is the second distance L2. In this embodiment, a conductive layer may be firstly formed on the semiconductor layer SE. The conductive layer covers the conductive pattern CP and the semiconductor layer SE at the same time. Then, a photolithography process and an etching process are performed to the conductive layer to form the first electrode E1 and the second electrode E2. The first electrode E1 is disposed on the conductive pattern CP, and is electrically connected with the conductive pattern CP. It should be particularly noted that the distance between the conductive pattern CP and the second electrode E2 (i.e. the second distance L2) is smaller than the distance between the first electrode E1 and the second electrode E2 (i.e. the first distance L1). In other words, compared with the first electrode E1, the conductive pattern CP is closer to the second electrode E2. In this embodiment, the first distance L1 is from 3 um to 4 um, for example, and the second distance L2 is from 1 um to 3 um, for example. The second electrode E2 surrounds the first electrode E1, for example. In addition, the first electrode E1 is in a strip shape, for example, and the second electrode E2 is in a U-shape, for example. However, the invention is not limited thereto. In other words, the first electrode E1 and the second electrode E2 may have other configurations. The first electrode E1 and the second electrode E2 are usually formed of a metallic material. However, the invention is not limited thereto. In other embodiments, the first electrode E1 and the second electrode E2 may also be formed of other conductive materials (e.g. an alloy, nitride of a metallic material, oxide of a metallic material, oxynitride of a metallic material, etc.) or a stack layer of a metallic material and other conductive materials.

Then, an insulation layer IL is formed on the substrate S. The insulation layer IL covers the first electrode E1 and the second electrode E2, the conductive pattern CP, and the semiconductor layer SE exposed between the first electrode E1 and the second electrode E2. A material of the insulation layer IL may be selected from an inorganic material, an organic material, other suitable materials, or a combination thereof. The inorganic material is, for example, silicon oxide, silicon nitride, silicon oxynitride, other suitable materials, or a stack layer of at least two of the materials. In this embodiment, the insulation layer IL may fully cover the substrate S. However, the invention is not limited thereto. In other embodiments, the insulation layer IL may also be implemented in other suitable configurations. Moreover, in other embodiments, a subsequent step of disposing a contact hole (not shown) in the insulation layer IL to electrically connect a pixel electrode may be included. Alternatively, other regular means for connecting the thin film transistor with other components in this field may also be applicable. However, no further details in this respect will be provided below.

In this embodiment, a thin film transistor 10 includes the gate GE, the gate insulation layer GI, the semiconductor layer SE, the conductive pattern CP, the first electrode E1, and the second electrode E2. The gate GE is disposed on the substrate S. The gate insulation layer GI is disposed on the substrate S to cover the gate GE. The semiconductor layer SE is disposed on the gate insulation layer GI. The conductive pattern CP is disposed on the semiconductor layer SE. The first electrode E1 and the second electrode E2 are disposed on the semiconductor layer SE. The first distance L1 is formed between the first electrode E1 and the second electrode E2. The first electrode E1 is one of the source and the drain, while the second electrode E2 is the other of the source and the drain. The conductive pattern CP is electrically connected with the first electrode E1. The second distance L2 is formed between the conductive pattern CP and the second electrode E2 to define the channel CH. In addition, the second distance L2 is smaller than the first distance L1. In this embodiment, the conductive pattern CP is, for example, disposed between the first electrode E1 and the semiconductor layer SE. In addition, the thin film transistor 10, for example, further includes the insulation layer IL covering the first electrode E1 and the second electrode E2, the conductive pattern CP, and the semiconductor layer SE exposed between the first electrode E1 and the second electrode E2.

In this embodiment, the first electrode E1 is formed on the conductive pattern

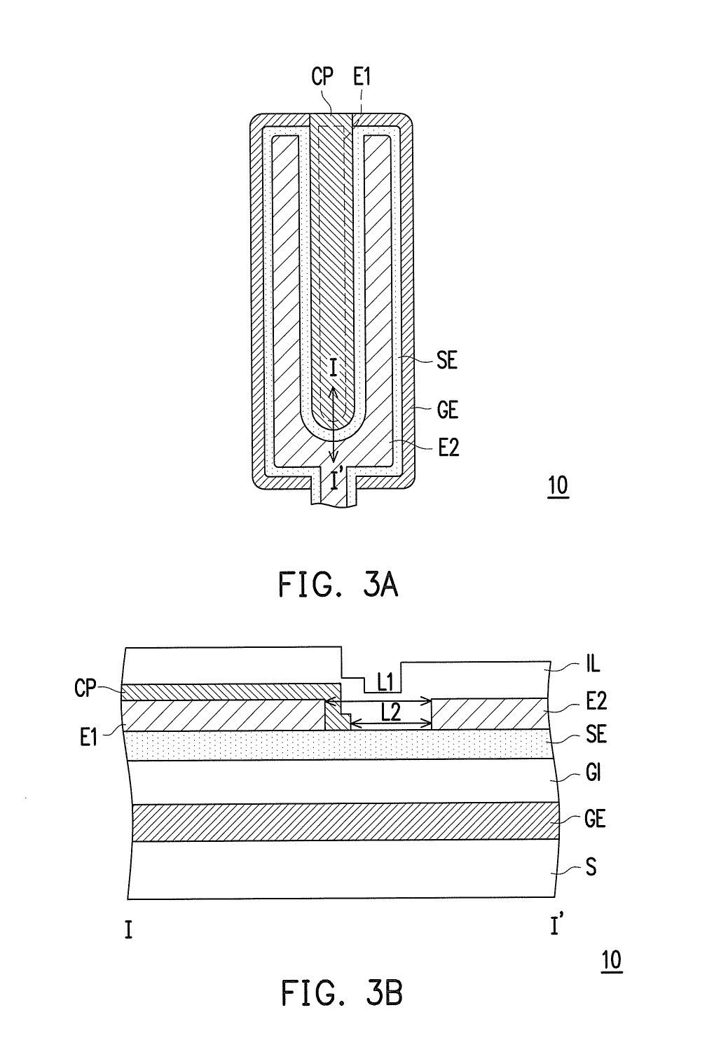

CP, for example. However, the invention is not limited thereto. For example, in another embodiment, the conductive pattern CP may also be formed on the first electrode E1, as shown in FIGS. 3A and 3B (where illustration of the gate insulation layer GI and the insulation layer IL are omitted). In other words, the first electrode E1 and the second electrode E2 are firstly formed on the semiconductor layer SE, and the first distance L1 is formed between the first electrode E1 and the second electrode E2. Then, the conductive pattern CP is formed on the first electrode E1, such that the conductive pattern CP covers the first electrode E1 and extends onto the semiconductor layer SE toward the second electrode E2. In addition, the second distance L2 is formed between the conductive pattern CP and the second electrode E2. In other words, the first electrode E1 is disposed between the conductive pattern CP and the semiconductor layer SE, for example.

Generally speaking, a length of the channel is defined by the distance between the source and the drain. In view of the trends of slim bezel design of a panel, a size of the transistor also needs to be reduced. However, since the source and the drain are usually formed by patterning the same conductive layer, the distance between the source and the drain (i.e. the length of the channel) is unable to be reduced due to limitation on exposure resolution. Therefore, a space taken up by the transistor is unable to be reduced. In the embodiment above, by forming the conductive pattern CP above or under one of the source (e.g. the second electrode E2) and the drain (e.g. the first electrode E1), the channel CH is formed between the conductive pattern CP and the other of the source (e.g. the second electrode E2) and the drain (the first electrode E1). In this way, the length of the channel may be defined based on a position where the conductive pattern CP is formed or the extent that the conductive pattern CP extends toward the second electrode E2, such that the channel length is reduced from the first distance L1 between the source and the drain (i.e. the first electrode E1 and the second electrode E2) to the second distance L2. In this way, the issue that the length of the channel is limited by the exposure resolution of an exposing machine may be solved without the needs of purchasing additional equipment and using a special mask. Accordingly, the length of the channel may be shortened, and thus the space taken up by the transistor may be reduced.

Moreover, the fabricating process of the thin film transistor above may be used for a circuit with a gate-in-panel (GIP) design, so as to be integrated with the conventional panel fabricating process. For example, the fabricating process of the thin film transistor may be used with the fringe-field switching (FFS) technology, such that the conductive pattern and the pixel electrode are fabricated together. In this way, it is not necessary to additionally add a fabricating process and a mask, so the cost for the mask is saved. Besides, by designing a different channel length (i.e. the second distance), thin film transistors having a short length channel design in different conditions may be easily fabricated. The short length channel design of the thin film transistor is capable of increasing a driving current of each component of thin film transistor in the GIP circuit. Thus, the size of the thin film transistor may be reduced, and performance of the GIP circuit may be improved. Moreover, since the size of the thin film transistor is reduced and the performance thereof is improved, the issue of insufficient space for a GIP layout due to the slim bezel may be solved, and the requirement of the targeted high resolution panel with a slim bezel is met.

In view of the foregoing, by forming the conductive pattern above or under one of the source and the drain, the channel is formed between the conductive pattern and the other of the source and the drain in the invention. In this way, the length of the channel is controlled and reduced by the position where the conductive pattern is formed, so as to overcome the issue that the length of the channel is limited by the exposure resolution of the exposing machine. Also, it is not necessary to use a special mask. Besides, fabrication of the thin film transistor may be integrated with the conventional panel fabricating process, and it is not necessary to use specific fabricating equipment, nor add an additional fabricating process and a mask. Therefore, the cost of fabricating a panel does not increase significantly. Furthermore, since the thin film transistor has a higher driving current, the size of the thin film transistor may be reduced to meet the requirement of the targeted high resolution panel with a slim bezel.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method of fabricating a thin film transistor, comprising following steps:
forming a gate on a substrate;
forming a gate insulation layer on the substrate to cover the gate;
forming a semiconductor layer on the gate insulation layer;
forming a conductive pattern on the semiconductor layer; and
forming a first electrode and a second electrode on the semiconductor layer, wherein a first distance is formed between the first electrode and the second electrode, the first electrode is one of a source and a drain, and the second electrode is the other of the source and the drain, and
the conductive pattern is electrically connected with the first electrode, and a second distance is formed between the conductive pattern and the second electrode to define a channel, wherein the second distance is smaller than the first distance.

2. The method of claim 1, wherein the first electrode is formed on the conductive pattern.

3. The method of claim 1, wherein the conductive pattern is formed on the first electrode.

4. The method of claim 1, further comprising a step of forming an insulation layer, wherein the insulation layer covers the first electrode and the second electrode, the conductive pattern, and the semiconductor layer exposed between the first electrode and the second electrode.

5. The method of claim 1, wherein the first distance is from 3 um to 4 um, and the second distance is from 1 um to 3 um.

6. A thin film transistor, comprising:
a gate, disposed on a substrate;
a gate insulation layer, disposed on the substrate to cover the gate;
a semiconductor layer, disposed on the gate insulation layer;
a conductive pattern, disposed on the semiconductor layer; and
a first electrode and a second electrode, disposed on the semiconductor layer, wherein a first distance is formed between the first electrode and the second electrode, the first electrode is one of a source and a drain, and the second electrode is the other of the source and the drain,
wherein the conductive pattern is electrically connected with the first electrode, a second distance is formed between the conductive pattern and the second electrode to define a channel, and the second distance is smaller than first distance.

7. The thin film transistor of claim 6, wherein the conductive pattern is disposed between the first electrode and the semiconductor layer.

8. The thin film transistor of claim 6, wherein the first electrode is disposed between the conductive pattern and the semiconductor layer.

9. The thin film transistor of claim 6, further comprising an insulation layer, wherein the insulation layer covers the first electrode and the second electrode, the conductive pattern, and the semiconductor layer exposed between the first electrode and the second electrode.

10. The thin film transistor of claim 6, wherein the first distance is from 3 um to 4 um, and the second distance is from 1 um to 3 um.
